(19) United States
(12) Patent Application Publication
(10) Pub. No.: US 2025/0258434 A1
(43) Pub. Date: Aug. 14, 2025

(54) DEPOSITION OF RESIST UNDERLAYER WITH REDUCED SP2 CARBON CONTENT

(71) Applicant: Applied Materials, Inc., Santa Clara, CA (US)

(72) Inventors: Sudha RATHI, San Jose, CA (US); Unnati JOSHI, Fremont, CA (US); Guangyan ZHONG, Sunnyvale, CA (US); Pramit MANNA, Santa Clara, CA (US); Karthik JANAKIRAMAN, San Jose, CA (US)

(21) Appl. No.: 19/051,620

(22) Filed: Feb. 12, 2025

Related U.S. Application Data
(60) Provisional application No. 63/552,453, filed on Feb. 12, 2024.

(51) Int. Cl. G03F 7/16; G03F 7/00; G03F 7/004

(52) U.S. Cl. CPC G03F 7/161; G03F 7/0043; G03F 7/70033

(57) ABSTRACT

The present disclosure generally relates to the fabrication of integrated circuits. More particularly, embodiments described herein provide techniques for forming resist underlayers having reduced sp2 hybridized carbon content for improving EUV lithography performance. In one embodiment, a method of processing a substrate is provided. The method includes flowing an underlayer precursor gas into a process chamber having a substrate and generating a plasma in the process chamber by applying a first RF bias for forming a resist underlayer on the substrate.

### CROSS-REFERENCE TO RELATED APPLICATIONS

This application claims the benefit of U.S. Provisional Patent Application Ser. No. 63/552,453, filed Feb. 12, 2024, which is incorporated by reference herein in its entirety.

### BACKGROUND

### Field

Embodiments of the present disclosure generally relate to the field of semiconductor processing and, in particular, to methods of fabricating integrated circuits using extreme ultraviolet (EUV) lithography.

### Description of the Related Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components reduce to the sub-micron scale, it is now necessary to use low resistivity conductive materials as well as low dielectric constant insulating materials to obtain suitable electrical performance from such components.

The demands for greater integrated circuit densities also impose demands on the process sequences used in the manufacture of integrated circuit components. For example, in process sequences that use conventional photolithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer.

As pattern dimensions are reduced, extreme ultraviolet (EUV) exposure is expected to be the method of choice for single exposure lithography to achieve required critical dimension (CD) targets in the sub 20-nm region and beyond. EUV lithography uses a far smaller wavelength (e.g, 13.5 nm) than the 193 nm wavelengths of the conventional techniques to scale down the feature sizes on the IC chips. However, EUV lithography is not without its challenges. EUV lithography process performance is determined based on its resolution, line width roughness (LWR), and sensitivity. LWR is a measure of the variation of the width of the lines formed by the lithography process. LWR reflect linewidth fluctuations that may lead to variations in device characteristics. As CD for integrated circuits continued to shrink, linewidth fluctuations may therefore play an increasingly significant role in CD error budget for lithography. Sensitivity can be further defined by the amount of energy or dose, needed to reach a certain feature size—sometimes also referred to as dose to size (DTS) ratio. Sensitivity of the EUV photoresist therefore also refers to the minimum dose of energy necessary to image the EUV photoresist.

Due to the low efficiency of EUV power sources, the limited amount of available EUV energy often requires exposure times to be long (e.g., a high DTS), resulting in low throughput. Higher DTS ratio due to low sensitivity by the EUV photoresist also increases the cost of lithography and makes the EUV lithography technology expensive to make applicable for high volume manufacturing. High sensitivity therefore became a critical requirement for EUV photoresists. Using a highly sensitive photoresists requires less exposure time equating to a smaller DTS ratio which in turn translates to increased efficiency of the process and throughput. However, the resulting reduction of the DTS ratio due to higher sensitive corresponds to a smaller number of EUV photons and a pronounced impact on the photon shot-noise that can cause increases in the LWR and result in highly rough profiles that can ultimately lead to defects and failures.

One of the main challenge in EUV photoresist design is therefore to simultaneously achieve improvements in sensivity (e.g., lower DTS ratio) and LWR necessary for industry targets. Accordingly, there is a need in the art for methods to improve EUV photoresist DTS ratio, while improving or without degrading corresponding LWR.

### SUMMARY

Embodiments of the present disclosure generally relate to the fabrication of integrated circuits. More particularly, the embodiments described herein provide techniques for deposition of a resist underlayer having reduced sp2 hybridized carbon content to improve EUV photoresist performance by reducing the DTS ratio of the EUV photoresist. In some embodiments, the reduced sp2 hybridized carbon content includes carbon functional group in the about 1600 cm⁻¹, about 1700 cm⁻¹, about 2800 cm⁻¹, and/or about 3000 cm⁻¹ frequency range.

In one embodiment, a method of processing a substrate is provided: The method includes flowing a underlayer precursor gas into a processing volume of a process chamber having a substrate disposed on a substrate support. The method also includes generating a plasma in the processing volume by applying a bias to the substrate support, and forming a resist underlayer on the substrate, wherein the processing volume is maintained at a temperature between about −50 degrees Celsius and about 600 degrees Celsius.

In some embodiments, the underlayer precursor gas comprises a saturated hydrocarbon precursor. In some embodiments, the bias is provided at a RF power between about 10 Watts and about 3000 Watts, and at a frequency of between about 200 KHz to about 80 MHz.

In another embodiment, a method of processing a substrate is provided. The method includes flowing an underlayer precursor gas into a processing volume of a process chamber having a substrate disposed on a substrate support, wherein the processing volume is maintained at a pressure between about 0.1 mTorr and about 100 Torr. The method also includes generating a plasma in the processing volume by applying a RF bias to the substrate support, and forming a resist underlayer on the substrate. When forming the resist underlayer, the processing volume is maintained at a temperature between about 10 degrees Celsius and about 600 degrees Celsius. Lastly, a patterned photoresist is formed over the resist underlayer. In some embodiments, forming the patterned photoresist comprises subjecting a photoresist to a dose of EUV radiation comprising a DTS ratio that is less than about 60 mJ/cm².

In a further embodiment, a method of processing a substrate is provided. The method includes flowing a underlayer precursor gas into a processing volume of a process chamber having a substrate disposed on a substrate support and generating a plasma in the processing volume for forming a resist underlayer on the substrate. The method also includes forming a metal oxide photoresist over the resist underlayer, exposing the metal oxide photoresist to EUV radiation with a dose comprising a DTS ratio less than about 60 mJ/cm², and developing the exposed metal oxide photoresist to form a patterned metal oxide photoresist.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a schematic cross-sectional view of a process chamber that can be used for the practice of the method of the present disclosure, according to certain embodiments described herein;

FIG. 2 depicts a flow diagram of a method 200 for forming a resist underlayer on a substrate using the apparatus of FIG. 1, according to certain embodiments described herein;

FIG. 3 depicts a flow diagram of a method 400 for forming a resist underlayer on a substrate, according to certain embodiments described herein; and

FIG. 4 depicts a flow diagram of a method 400 for forming a resist underlayer on a substrate, according to certain embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods of forming a resist underlayer for use in EUV lithography processes is described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

Embodiments described herein will be described below in reference to a PECVD process that can be carried out using any suitable thin film deposition system. Examples of suitable systems include the CENTURA® systems which may use a DXZ® processing chamber, PRECISION 5000® systems, PRODUCER® systems, PRODUCER® GT™ systems, PRODUCER® XP Precision™ systems, PRODUCER® SE™ systems, Sym3® processing chamber, and Mesa™ processing chamber, all of which are commercially available from Applied Materials, Inc., of Santa Clara, Calif. Other tools capable of performing PECVD processes may also be adapted to benefit from the embodiments described herein. In addition, any system enabling the PECVD processes described herein can be used to advantage. The apparatus description described herein is illustrative and should not be construed or interpreted as limiting the scope of the embodiments described herein.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the processing steps disclosed may also be performed on an intermediate layer formed on the substrate as disclosed in more detail below, and the term “substrate surface” is intended to include such intermediate layer as the context indicates. Thus for example, where a film/layer or partial film/layer has been deposited onto a substrate surface, the exposed surface of the newly deposited film/layer becomes the substrate surface.

As used herein, “extreme UV”, “EUV”, or the like, refers to radiation in the approximate range of 10 nm to 124 nm. In some embodiments, EUV radiation (also referred to as EUV light) in the range of 10 nm to 15 nm. In one or more embodiments, EUV light at a wavelength of about 13.5 nm is employed.

In EUV photolithography, the demand for ever-decreasing feature sizes has also led to the use of thinner films to prevent pattern collapse. Accordingly, the thickness of the energy sensitive EUV photoresist may correspondingly be reduced in order to control pattern resolution. However, when thin photoresist are used, issues may occur such as collapse of the photoresist pattern, or the EUV photoresist alone not capturing an adequate EUV exposure dose. As such, a resist underlayer may therefore be used between the energy sensitive EUV photoresist and the underlying substrate material layers to help facilitate pattern transfer. The resist underlayer can be used to assist pattern transfer by smoothing out surface feature roughness of a substrate thereby improving exposure results. Resist underlayers can also contribute to improving EUV exposure results by normalizing the surface energy and increasing photoresist adhesion, both of which may assist in reducing the risk of pattern collapse. However, as the EUV photoresist thickness decreases, underlayer thickness should decrease too. Although a dense underlayer can improve selectivity by offering a strong contrast to the EUV photoresist, a dense underlayer also etches more slowly thereby increasing the resist's exposure to the etch chemistry. If the EUV photoresist is too thin as compared to the resist underlayer, the photoresist can erode away before the etch is complete.

Embodiments of the present disclosure described herein include methods of fabricating a resist underlayer that is both thin and capable of reducing a DTS ratio of a photoresist during exposure. The resist underlayer fabricated by the methods of the present disclosure have reduced or low sp2 hybridized carbon content when deposited on a substrate.

In EUV lithography, the change to modify the solubility of the photoresist during exposure is mainly initiated by the photoelectric effect where the absorption of photons from EUV radiation leads to the generation of photoelectrons. During exposure in EUV lithography, EUV photons are absorbed by the EUV photoresist material. This absorption of the EUV photon leads to the generation of photoelectrons that travels in random directions through the photoresist material. As the photoelectrons travel, the photoelectrons loses energy until the energy of the photoelectrons becomes close to the ionization potential of the photoresist molecule and is absorbed. The absorption of the photoelectrons leads to the ionization of the absorbing molecule and generation of secondary electrons that then go on to further ionize the photoresist and induce change in the photoresist material.

In EUV lithography, it was observed that uneven charge distribution in between atoms and high-energy sp2 bonds, such as those found in sp2 hybridized carbon content on the substrate surface, are the preferred sites for interaction by EUV photons and certain radicals from the photoresist during EUV exposure. In some instances, the already low number of EUV photons during exposure may be “wasted” when reacting with the molecules of the substrate surface as a result of its affinity to be attracted to high-energy sp2 hybridized carbon content of the resist underlayer. In some embodiments, disposing a resist underlayer having reduced sp2 hybridized carbon content between the substrate and the photoresist may therefore attract less EUV photons from the photoresist during exposure and allow for a reduction in the DTS ratio.

The resist underlayer fabricated by the methods of the present disclosure may be particularly useful for metal oxide photoresists (MOR) in EUV lithography, but may also be useful for other types of photoresists, such as chemically amplified photoresists (CAR). In some embodiments, reducing sp2 hybridized carbon content in the resist underlayer includes reducing, without limitation, the presence of C═C stretch functional groups. C═C stretch in alkenes, and ═C—H stretch in aromatics in the molecules of the resist underlayer. Reducing sp2 hybridized carbon content in the resist underlayer may also corresponding increase the sp3 hybridized carbon content of the resist underlayer. Once the resist underlayer is formed on the substrate, the EUV photoresist can be disposed over the resist underlayer for patterning. The resist underlayers fabricated according to the methods described herein may provide improved sensitivity and allow for a reduction in the DTS ratio during exposure without degrading LWR or minimum CD. In some embodiments, the resist underlayer allows about 30% or more reduction in the DTS ratio. Such decrease in dosage can in turn increase the substrate throughput during processing. Another advantage of the present disclosure is that EUV photoresist performance can be improved without the need for modifying the photoresist composition itself to make it more suitable for EUV applications.

Although the following discusses the application of the resist underlayer directly to the substrate surface, it will be appreciated that in some embodiments there may be one or more inter mediate layers applied to the substrate first. In such instances, the resist underlayer can then be applied to the upper most intermediate layer rather than to the substrate surface. Examples of possible intermediate layers that could be utilized include those selected from the group consisting of hard masks (including spin-on carbon), organic layers, carbon layers, organo-metallic layers, and barrier layers.

In some embodiments, the resist underlayer can be formed by vapor deposition, such as chemical vapor deposition (plasma enhanced and/or thermal). The resist underlayer may be formed using various reactant gas mixtures including precursors such as, but not limited to C₂H₂, C₃H₆, CH₄, and C₄H₈, saturated hydrocarbons such as propane (C₃H₈), butane (C₄H₁₀), pentane (C₅H¹²), hexane (C₆H₁₄), and cyclohexane (C₆H₁₂), and N, F, I, O, Si, B, W, Sn, Pb, and Ge containing functional groups in dopants, or combinations thereof. The deposition process may be carried out at temperatures ranging from −50 degrees Celsius to 600 degrees Celsius. The deposition process may be carried out at pressures ranging from 0.1 mTorr to 100 Torr in a processing volume.

The underlayer precursor gas may further include any one of, or a combination of any of He, Ar, of Xe as a dilution gas. The plasma (e.g., capacitive-coupled plasma) may be formed from either top and bottom electrodes or side electrodes. In other embodiments, the plasma may be inductively coupled plasma. The electrodes may be formed from a single powered electrode, dual powered electrodes, or more electrodes with multiple frequencies such as, but not limited to, 350 KHz, 2 MHZ, 13.56 MHZ, 27 MHz, 40 MHz, 60 MHz and 100 MHz, being used alternatively or simultaneously in a CVD system with any or all of the reactant gases listed herein to deposit the resist underlayer. Not to be bound by theory, but it is believed that reduced sp2 hybridized content in the resist underlayer can be achieved by one or more of the following processing parameters, including without limitation, reduced processing temperature, reduced high frequency RF plasma power, increased processing pressure, and use of saturated hydrocarbon precursors.

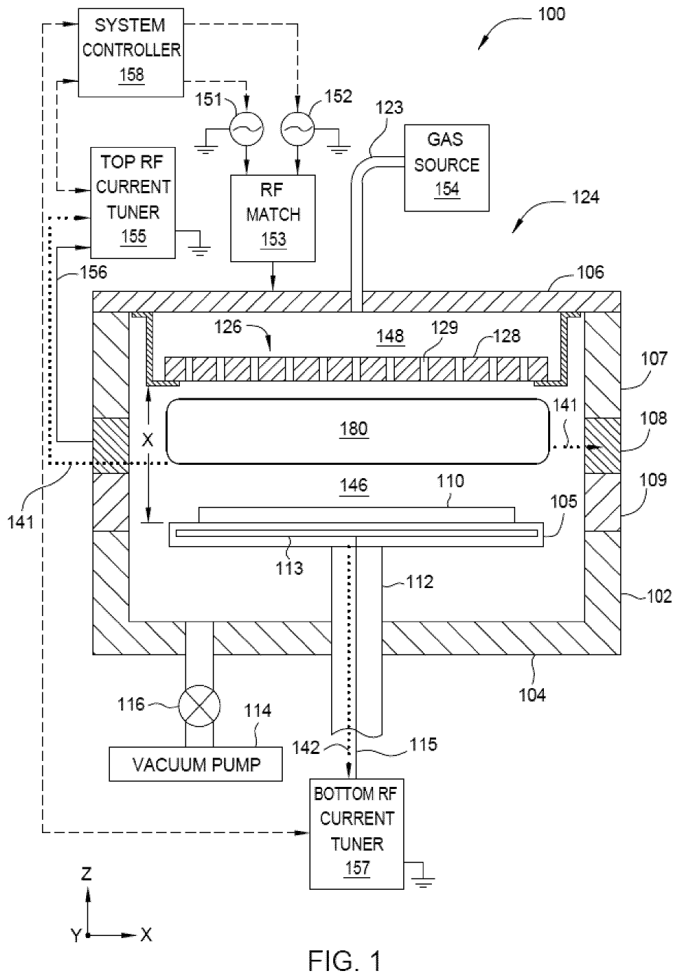

FIG. 1 is a schematic cross sectional view of a process chamber 100 that can be used to perform deposition of the resist underlayer, in accordance with embodiments described herein. By way of example, the embodiment of the process chamber 100 in FIG. 1 is described in terms of a PECVD system, but any other process chamber may fall within the scope of the embodiments, including other vapor deposition chambers or plasma deposition chambers. The process chamber 100 includes walls 102, a bottom 104, and a chamber lid 124 that together enclose a substrate support 105 and a processing volume 146. The process chamber 100 further includes a vacuum pump 114, a first RF generator 151, a second RF generator 152, an RF match 153, a gas source 154, a top RF current tuner 155, a bottom RF current tuner 157, and a system controller 158, each coupled externally to the process chamber 100 as shown.

The walls 102 and the bottom 104 may comprise an electrically conductive material, such as aluminum or stainless steel. Through one or more of the walls 102, a slit valve opening may be present that is configured to facilitate insertion of a substrate 110 into and removal of the substrate 110 from the process chamber 100. A slit valve configured to seal slit valve opening may be disposed either inside or outside of the process chamber 100. For clarity, no slit valve or slit valve opening is shown in FIG. 1.

The vacuum pump 114 is coupled to the process chamber 100 and is configured to adjust the vacuum level therein. As shown, a valve 116 may be coupled between the process chamber 100 and the vacuum pump 114. The vacuum pump 114 evacuates the process chamber 100 prior to substrate processing and removes process gas therefrom during processing through the valve 116. The valve 116 may be adjustable to facilitate regulation of the evacuation rate of the process chamber 100. The evacuation rate through the valve 116 and the incoming gas flow rate from the gas source 154 determine chamber pressure and process gas residency time in the process chamber 100.

The gas source 154 is coupled to the process chamber 100 via a tube 123 that passes through the chamber lid 124. The tube 123 is fluidly coupled to a plenum 148 between a backing plate 106 and a gas distribution showerhead 128 included in the chamber lid 124. During operation, process gas introduced into the process chamber 100 from the gas source 154 fills the plenum 148 and then passes through the gas passages 129 formed in the gas distribution showerhead 128 to uniformly enter the processing volume 146. In alternative embodiments, process gas may be introduced into the processing volume 146 via inlets and/or nozzles (not shown) that are attached to the walls 102 in addition to or in lieu of the gas distribution showerhead 128.

The substrate support 105 may include any technically feasible apparatus for supporting a substrate during processing by the process chamber 100, such as the substrate 110 in FIG. 1. In some embodiments, the substrate support 105 is disposed on a shaft 112 that is configured to raise and lower the substrate support 105. In one embodiment, the shaft 112 and the substrate support 105 may be formed at least in part from or contain an electrically conductive material, such as tungsten, copper, molybdenum, aluminum, or stainless steel. Alternatively or additionally, the substrate support 105 may be formed at least in part from or contain a ceramic material, such as aluminum oxide (Al₂O₃), aluminum nitride (AlN), silicon dioxide (SiO₂), and the like.

In some embodiments, the substrate support 105 may include a heater element (not shown) suitable for controlling the temperature of the substrate 110 supported on the top surface of the substrate support 105. The heater element 170 may be embedded in the substrate support 105. The substrate support 105 may be resistively heated by applying an electric current from a heater power source (not shown) to the heater element. The electric current supplied from the heater power source may also be regulated by the system controller 158 to control the heat generated by the heater element, thus maintaining the substrate 110 and the substrate support 105 at a substantially constant temperature during film deposition. The supplied electric current may be adjusted to selectively control the temperature of the substrate support 105 or the substrate 110 disposed thereon between about −50 degrees Celsius to about 600 degrees Celsius.

In embodiments in which the process chamber 100 is a capacitively coupled plasma chamber, the substrate support 105 may be configured to contain an electrode 113. In such embodiments, a metal rod 115 or other conductor is electrically coupled to the electrode 113 and is configured to provide a portion of a ground path for RF power delivered to the process chamber 100. That is, the metal rod 115 enables a RF power delivered to the process chamber 100 to pass through the electrode 113 and out of the process chamber 100 to ground. Together, the electrode 113 and the gas distribution showerhead 128 define the boundaries of the processing volume 146 in which plasma is formed. For example, during processing, the substrate support 105 and the substrate 110 may be raised and positioned closer to the lower surface of the gas distribution showerhead 128 to form the at least partially enclosed processing volume 146.

In some embodiments, the electrode 113 may also be configured to provide an electrical bias from a DC power source (not shown) to enable electrostatic clamping of the substrate 110 onto the substrate support 105 during plasma processing. In such embodiments, the substrate support 105 may also be an electrostatic chuck that generally includes a body comprising one or more ceramic materials suitable for use in a substrate support. In such embodiments, the electrode 113 may be a mesh, such as an RF mesh, or a perforated sheet of material made of molybdenum (Mo), tungsten (W), or other material with a coefficient of thermal expansion that is substantially similar to that of the ceramic material or materials included in the body of the substrate support 105.

The first RF generator 151 is a radio frequency (RF) power source configured to provide high-frequency power at a first RF frequency to a discharge electrode 126 via the RF match 153. Similarly, the second RF generator 152 is an RF power source configured to provide RF power at a second RF frequency to the discharge electrode 126 via RF match 153. In some embodiments, first RF generator 151 includes an RF power supply capable of generating RF currents at a high frequency (HF), for example, about 13.56 MHz. Alternatively or additionally, the first RF generator 151 includes a VHF generator capable of generating VHF power, such as VHF power at frequencies between about 20 MHz to 200 MHz or more, such as about 27 MHz or about 40 MHz. By contrast, the second RF generator 152 includes an RF power supply capable of generating RF currents at so-called low frequency (LF) RF, for example, about 350 kHz. Alternatively or additionally, the second RF generator 152 includes an RF generator capable of generating RF power at frequencies between about 1 kHz and about 1 MHz. The first RF generator 151 and the second RF generator 152 are configured to facilitate generation of a plasma in the processing volume 146 between the discharge electrode 126 and the substrate support 105.

The discharge electrode 126 may include a process gas distribution element, such as the gas distribution showerhead 128 (as shown in FIG. 1), and/or an array of gas injection nozzles, through which process gases are introduced into the processing volume 146. The discharge electrode 126, i.e., the gas distribution showerhead 128, may be oriented substantially parallel to the surface of the substrate 110, and capacitively couples plasma source power into the processing volume 146, which is disposed between the substrate 110 and the gas distribution showerhead 128.

The RF match 153 may be any technically feasible impedance matching apparatus that is coupled between the first RF generator 151 and the powered electrode of the process chamber 100, i.e., the gas distribution showerhead 128. The RF match 153 is also coupled between the second RF generator 152 and the powered electrode of the process chamber 100. The RF match 153 is configured to match a load impedance (the process chamber 100) to the source or internal impedance of a driving source (the first RF generator 151, the second RF generator 152) to enable the maximum transfer of RF power from the first RF generator 151 and the second RF generator 152 to the process chamber 100.

Forming a portion of the walls 102 are an upper isolator 107, a tuning ring 108, and a lower isolator 109. The upper isolator 107 is configured to electrically isolate the tuning ring 108, which is formed from an electrically conductive material, from the backing plate 106, which in some embodiments is energized with RF power during operation. Thus, upper isolator 107 is positioned between the backing plate 106 and the tuning ring 108, and prevents the tuning ring 108 from being energized with RF power via the backing plate 106. In some embodiments, the upper isolator 107 is configured as a ceramic ring or annulus that is positioned concentrically about the processing volume 146. Similarly, the lower isolator 109 is configured to electrically isolate the tuning ring 108 from the walls 102. The walls 102 are typically formed from an electrically conductive material, and can therefore act as a ground path for a portion of RF power delivered to the process chamber 100 during processing. Thus, the lower isolator 109 enables the tuning ring 108 to be part of a different ground path for RF power delivered to the process chamber 100 than that of the walls 102. In some embodiments, the upper isolator 107 is configured as a ceramic ring, or is configured to include a ceramic ring that is positioned concentrically about the processing volume 146.

The tuning ring 108 is disposed between the upper isolator 107 and the lower isolator 109, is formed from an electrically conductive material, and is disposed adjacent the processing volume 146. For example, in some embodiments, the tuning ring 108 is formed from a suitable metal, such as aluminum, copper, titanium, or stainless steel. In some embodiments, the tuning ring 108 is a metallic ring or annulus that is positioned concentrically about the substrate support 105 and the substrate 110 during processing of the substrate 110. In addition, the tuning ring 108 is electrically coupled to ground via the top RF current tuner 155 via a conductor 156, as shown. Thus, the tuning ring 108 is not a powered electrode, and is generally disposed outside of and around the processing volume 146. In one example, the tuning ring 108 is positioned in a plane substantially parallel with the substrate 110, and is part of a ground path for the RF energy used to form a plasma in the processing volume 146. As a result, an additional RF ground path 141 is established between the gas distribution showerhead 128 and ground, via the top RF current tuner 155. Thus, by changing the impedance of the top RF current tuner 155 at a particular frequency, the impedance for the RF ground path 141 at that particular frequency changes, causing a change in the RF field that is coupled to the tuning ring 108 at that frequency. Therefore, the shape of plasma in the processing volume 146 may be independently modulated along the +/−X and Y-directions for the RF frequency associated with either the first RF generator 151 or the second RF generator 152. That is, the shape, volume or uniformity of the plasma formed in the processing volume 146 may be independently modulated for multiple RF frequencies across the surface of the substrate 110 by use, for example, of the tuning ring 108 or vertically between the substrate 110 and the gas distribution showerhead 128 using the electrode 113.

The system controller 158 is configured to control the components and functions of the process chamber 100, such as the vacuum pump 114, the first RF generator 151, the second RF generator 152, the RF match 153, the gas source 154, the top RF current tuner 155, and the bottom RF current tuner 157. As such, the system controller 158 receives sensor inputs, e.g., voltage-current inputs from the top RF current tuner 155 and the bottom RF current tuner 157, and transmits control outputs for operation of the process chamber 100. The functionality of the system controller 158 may include any technically feasible embodiment, including via software, hardware, and/or firmware, and may be divided between multiple separate controllers associated with the process chamber 100.

The top RF current tuner 155, as noted above, is electrically coupled to the tuning ring 108 and is terminated to ground, thus providing a controllable RF ground path 141 for the process chamber 100. Similarly, the bottom RF current tuner 157 is electrically coupled to the metal rod 115 and is terminated to ground, thus providing a different controllable RF ground path 142 for the process chamber 100. As described herein, the top RF current tuner 155 and the bottom RF current tuner 157 are each configured to control the flow of RF current to ground at multiple RF frequencies. Thus, the distribution of RF current at a first RF frequency between the tuning ring 108 and the metal rod 115 can be controlled independently from the distribution of RF current at a second RF frequency between the tuning ring 108 and the metal rod 115.

A plasma 180 is formed in the processing volume 146 in between the electrode 113 and the discharge electrode 126. A distance or “spacing” between the bottom surface of the electrode 113 and a top surface of the substrate support 105 is represented by “x”.

Other deposition chambers may also benefit from the present disclosure and the parameters listed above may vary according to the particular deposition chamber used to form the amorphous carbon layer. For example, other deposition chambers may have a larger or smaller volume, requiring gas flow rates that are larger or smaller than those recited for deposition chambers available from Applied Materials, Inc. In one embodiment, carbon gapfill layer may be deposited using a PRODUCER® XP Precision™ processing system, which is commercially available from Applied Materials, Inc., Santa Clara, California.

Proper control and regulation of the gas flows from the gas source 154 may be performed by mass flow controllers (not shown) and the system controller 158. The gas distribution showerhead 128 allows process gases from the gas source 154 to be uniformly distributed and introduced into the processing volume 146.

The first RF generator 151 and the second RF generator 152 may produce power at the same frequency or a different frequency. In some embodiments, one or both of the first RF generator 151 and the second RF generator 152 may independently produce power at a frequency from about 350 KHz to about 100 MHZ (e.g., 350 KHz, 2 MHz, 13.56 MHZ, 27 MHz, 40 MHz, 60 MHz, or 100 MHZ). In some embodiments, the first RF generator 151 may produce power at a frequency of 13.56 MHz and the second RF generator 152 may produce power at a frequency of 2 MHZ, or vice versa. RF power from one or both of the first RF generator 151 and second RF generator 152 may be varied in order to tune the generated plasma.

Not to be bound by theory, but it is believed that during exposure in EUV lithography, uneven charge distributions in between atoms with high-energy sp2 bonds, such as those found in sp2 hybridized carbon atoms, are the preferred sites for interaction by certain radicals and photons due to an affinity to bring the sp2 bonds to a lower energy state. In some instances, EUV photons during exposure may therefore be attracted to and absorbed by molecules in the substrate surface below the photoresist (e.g., the resist underlayer) without interacting with the photoresist, thereby further reducing the already low number of EUV photons available for changing the photoresist during exposure. The further reduction in EUV photons for changing the solubility of the photoresist may in turn cause an increase in the exposure dose needed, which correspondingly decreases throughput. The potential for additional stochastic varability caused by such photon absorption and/or energy release from the resist underlayer further increases stochastic variabilities that have the potential to deteriorate the EUV photoresist performance.

In analyzing the reaction of films having differing compositions of sp2 hybridized carbon content with EUV photons, it was observed that films initially having greater sp2 hybridized carbon content exhibited a greater change after exposure to UV photons, than films with lower sp2 hybridized carbon content. Specifically, after exposure to UV photons, films with greater sp2 hybridized carbon atoms exhibited a substantial further increase in total sp2 hybridized carbon content. In contrast, films with lower sp2 hybridized carbon content initially exhibit little to no change in corresponding sp2 hybridized carbon content after UV exposure.

The specific changes in carbon content of films with varying sp2 hybridized carbon content as a result of UV exposure were further analyzed using FTIR analysis. In films with greater initial sp2 hybridized carbon content (e.g., initial FTIR analysis showing peaks at frequencies/wave numbers of about 1600 cm⁻¹ and about 1700 cm⁻¹ with about −0.015 and −0.035 absorbance, respectively), the results from FTIR analysis indicated a change in the absorbance band of the analyzed surface after UV exposure. Specifically, there was a greater increase in absorbance at the frequency/wave number peaks corresponding to the sp2 hybridized carbon content (e.g., about 1600 cm⁻¹ and about 1700 cm⁻¹). The increase in absorbance indicates a corresponding increase in sp2 hybridized carbon atom content in the analyzed films with such peaks at between about 1600 cm⁻¹ and about 1670 cm⁻¹, and between about 1600 cm⁻¹ and about 1700 ⁻¹ in the infrared spectrum corresponding to C═C stretch functional groups and C═C stretch in alkenes, respectively.

In contrast, in films initially having lower sp2 hybridize carbon content (e.g., initial FTIR analysis showing absorbance bands with peaks at frequencies/wave numbers of about 1600 cm⁻¹ and about 1700 cm⁻¹ of about −0.055 and −0.065 absorbance, respectively), the results from FTIR analysis indicated little to no change in the absorbance band of the analyzed film after UV exposure. The little to no change in absorbance for films with lower sp2 hybridize carbon content indicates little to no change in the amount of sp2 hybridize carbon content after UV exposure.

In some embodiments, similar observations regarding reactions to EUV exposure and corresponding changes in absorbance (via FTIR analysis) were also observed with regards to peaks at frequencies/wave numbers between about 2800 cm⁻¹ and about 3000 cm⁻¹, corresponding to (═C)C—H stretching in alkenes and aromatic groups (e.g, cyclohexene), respectively, in the analyzed carbon films.

Without being bound by theory, the foregoing indicates that resist underlayers similarly with lower amounts of sp2 hybridized carbon content may generally be less reactive to UV photons from the photoresist during EUV exposure. As disposed between the substrate and the photoresist during EUV photolithography, resist underlayers with reduced sp2 hybridized carbon content may in turn allow for less “wasting” of UV photons during EUV exposure. It was also observed that when films with reduced sp2 hybridized carbon content were implemented as resist underlayers, the decrease in the affinity of EUV photons to the resist underlayer in turn provided for improved photoresist performance by allowing for corresponding reduction in DTS ratio during exposure and improvement in LWR.

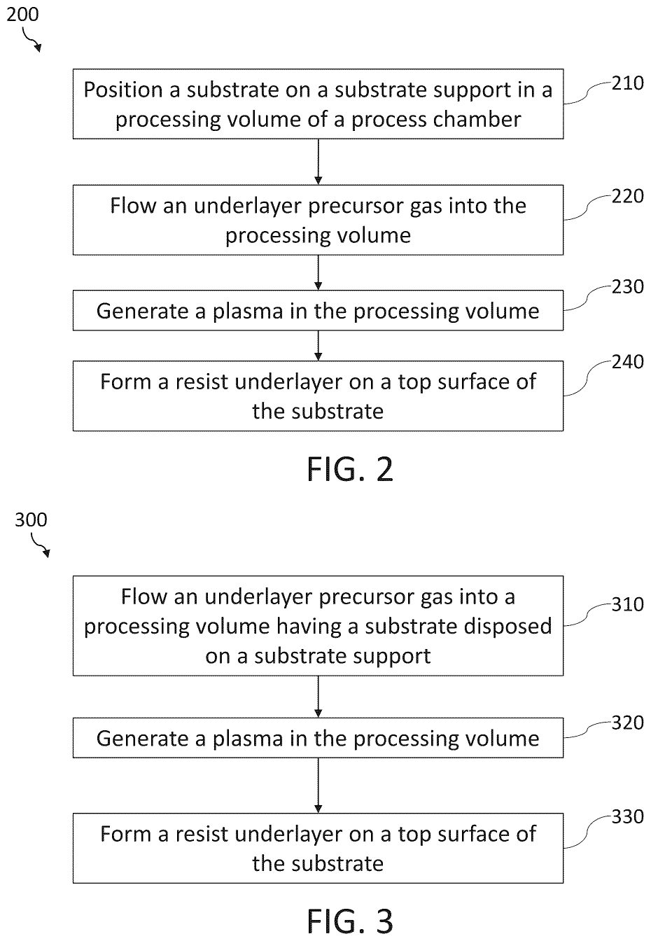

FIG. 2 depicts a flow diagram of a method 200 for forming a resist underlayer on a substrate, in accordance with certain embodiments of the present disclosure. The resist underlayer may be formed directly on the substrate, or on the upper most intermediate layer of one or more intermediate layers disposed on the substrate first. Although the method 200 is described below with reference to a resist underlayer that may be formed on a substrate utilized in EUV lithography, the method 200 may also be used to advantage in other device manufacturing applications. Further, it should also be understood that the operations depicted in FIG. 2 may be performed simultaneously and/or in a different order than the order depicted in FIG. 2.

The method 200 begins at operation 210 by positioning a substrate into a process chamber, such as the process chamber 100 depicted in FIG. 1. The substrate may be the substrate 110 depicted in FIG. 1. The substrate 110 may be any microelectronic substrate containing silicon, silicon oxide, aluminum, aluminum oxide, tungsten, germanium, combinations therefore, and the like. In certain embodiments, the substrate may be a material such as crystalline silicon (e.g., Si<100> or Si<111>), silicon oxide, strained silicon, silicon germanium, doped or undoped polysilicon, doped or undoped silicon substrates and patterned or non-patterned substrates silicon on insulator (SOI), carbon doped silicon oxides, silicon nitride, doped silicon, germanium, gallium arsenide, glass, sapphire. The substrate may have various dimensions, such as 200 mm, 300 mm, and 450 mm or other diameter substrates, as well as, rectangular or square panels. Unless otherwise noted, embodiments and examples described herein are conducted on substrates with a 200 mm diameter, a 300 mm diameter, or a 450 mm diameter substrate.

The substrate 110 may be positioned on a substrate support in the processing volume of the process chamber. For example, the substrate 110 may be positioned on a top surface of the substrate support 105 in process chamber 100. The method 200 may be performed on the substrate 110 to form the resist underlayer on a top surface of the substrate 110 in preparation for subsequently performing an EUV lithography process for pattern transfer.

In operation 220, an underlayer precursor gas is flowed into the processing volume 146. The underlayer precursor gas may be flowed from the gas panel 130 into the processing volume 146 either through the gas distribution assembly 120 or via the sidewall 101. In some embodiments, the underlayer precursor gas may comprise a saturated precursor, such as a saturated hydrocarbon precursor. The underlayer precursor gas may further include an inert gas, a dilution gas, a carrier gas or combinations thereof. The hydrocarbon precursor can be any liquid or gas, though the preferred precursor would be vapor at room temperature to simplify the hardware needed for material metering, control and delivery to the chamber.

In some embodiments, the underlayer precursor gas comprises a hydrocarbon precursor with a general formula CₓH_{y}, where x has a range of between 1 and 20 and y has a range of between 1 and 20, to add carbon to the resist underlayer. Suitable hydrocarbon precursors include, for example, C₂H₆, C₃H₆, CH₄, C₄H₁₀, 1,3-dimethyladamantane, bicyclo [2.2.1] hepta-2,5-diene (2,5-Norbornadiene), adamantine (C₁₀H₁₆), norbornene (C₇H₁₀), or combinations thereof. In some embodiments, the hydrocarbon precursor is a saturated hydrocarbon precursor containing only carbon-carbon single bonds.

In some embodiments, the hydrocarbon precursor is a saturated precursor such as an alkane (e.g., CₙH₂ₙ₊₂, wherein n is between 1 and 20). Suitable saturated hydrocarbon precursors include, for example, alkanes such as methane (CH₄), ethane (C₂H₆), propylene (C₃H₆), propane (C₃H₈), butane (C₄H¹⁰) and its isomer isobutane, pentane (C₅H₁₂), hexane (C₆H₁₄) and its isomers 2-methylpentane, 3-methylpentane, 2,3-dimethylbutane, and 2,2-dimethyl butane, cyclohexane (C₆H₁₂) and its isomers isopentane and neopentane, or combinations thereof.

In some embodiments, the hydrocarbon precursor is an alkyne (e.g., CₙH₂ₙ₋₂, wherein n is between 1 and 20). Suitable hydrocarbon precursors include, for example, alkynes such as acetylene (C₂H₂), propyne (C₃H₄), 1-Butyne (C₄H₆), or combinations thereof.

In some embodiments, the underlayer precursor gas comprises one or more dopant precursors, such as nitrogen (N), fluorine (F), iodine (I), oxygen (O), silicon (Si), boron (B), tungsten (W), tin (Sn), lead (Pb), and germanium (Ge) containing gases, or mixtures thereof. For example, the underlayer precursor gas may comprise dopant precursors such as trimethylborane (TMB), diborane (B2H6), phosphine (PH3), arsine (AsH3), and substituted phosphines and arsines, or mixtures thereof. The dopant precursors may be carried by a carrier gas, or diluted in a dilution gas, for example helium, argon, nitrogen, or hydrogen, or any mixture thereof.

In some embodiments, the underlayer precursor gas further comprises one or more dilution gases. Suitable dilution gases such as hydrogen (H₂), helium (He), argon (Ar), xenon (Xe), or combinations thereof, among others, may be added to the gas mixture, if desired. Alternatively, dilution gases may not be used during the deposition. In some embodiments, the underlayer precursor gas further comprises an inert gas. In some embodiments, an inert gas, such as argon (Ar) and/or helium (He) may be supplied with the underlayer precursor gas into the processing volume 146.

In some embodiments, the underlayer precursor gas further comprises an inert gas. In some embodiments, an inert gas, such as argon (Ar) and/or helium (He) may be supplied with the underlayer precursor gas into the processing volume 146. Other inert gases, such as nitrogen (N₂) and nitric oxide (NO), may also be used to control the density and deposition rate of the resist underlayerer. Additionally, a variety of other processing gases may be added to the underlayer precursor gas to modify properties of the resist underlayer. In one embodiment, the other processing gases may be reactive gases, such as hydrogen (H₂), ammonia (NH₃), a mixture of hydrogen (H₂) and nitrogen (N₂), or combinations thereof. The addition of H₂ and/or NH₃ may assist in increasing the hydrogen saturation of the deposited resist underlayer layer.

At operation 230, a plasma is generated from the underlayer precursor gas in the processing volume 146 of the process chamber 100. The plasma may be generated by applying a first RF bias to the processing volume 146. The first RF bias may be from about 1 Watt and about 3000 Watts at a frequency of from about 200 kHz to about 80 MHz (e.g., 350 KHz, 2 MHZ, 13.56 MHZ, 27 MHz, 40 MHz, 60 MHz, or 80 MHz). In one embodiment, the first RF bias is provided from the first RF generator 151 at a power between about 10 Watts and about 3000 Watts, such as about 200 Watts at a frequency of about 13.56 MHz.

In some embodiments, operation 230 further comprises applying a second RF bias to the processing volume 146 from the second RF generator 152. The second RF bias may be from about 10 Watts and about 3000 Watts at a frequency of from about 350 KHz to about 100 MHz (e.g., 350 KHz, 2 MHz, 13.56 MHZ, 27 MHz, 40 MHz, 60 MHz, or 100 MHZ). In one embodiment, the second RF bias is provided at a power between about 800 Watts and about 1200 Watts at a frequency of about 2 MHZ.

A density profile of the plasma may be adjusted by biasing the electrode 113 and/or the discharge electrode 126. The electrodes will typically be controlled to provide impedance for a selected current to flow through the electrodes. A resonant tuning circuit is typically coupled to the electrodes and to ground, and components for the resonant tuning circuit are selected, with at least one variable component, so the impedance can be adjusted dynamically to maintain the target current flow. The current flow through each electrode may be controlled to a value between about 0 A and about 30 A or between about 1 A and about 30 A.

In operation 240, the plasma generated in operation 230 is used to form the resist underlayer on the substrate. In some embodiments, the resist underlayer formed may have a thickness between about 10 Å and about 1000 Å, such as between about 30 Å and about 500 Å, such as between about 50 Å and about 300 Å.

In some embodiments, the flowing of the underlayer precursor gas from operation 320 is extended through operation 330 and may be performed from about 15 seconds to about 900 seconds, for example, for about 60 seconds to form the resist underlayer. In some embodiments, the process time may be extended to change and increase coverage. In some embodiments, the process conditions established during operation 220 and plasma formed during operation 330 are maintained during operation 340.

After the resist underlayer is formed in operation 240, an EUV photoresist can be formed over the resist underlayer. In some embodiments, the EUV photoresist is a metal oxide photoresist. The metal oxide photoresist can be a positive resist that becomes soluble upon exposure to EUV radiation, or a negative resist that becomes insoluble upon exposure to EUV radiation.

In some embodiments, the metal oxide photoresist may be a metal rich oxide layer that provides ample secondary electrons when excited by EUV radiation. A fully stoichiometric metal oxide layer does not yield as many electrons as the metal rich oxide layer. A metal rich oxide layer including a high Z metal and lower resistance are considered for the EUV process to reduce the EUV dose energies. The high Z metal refers to a metal having an atomic number greater than or equal to 40. In some embodiments, the metal oxide photoresist is a metal rich oxide layer including one or more of tin (Sn), indium (In), gallium (Ga), zinc (Zn), tellurium (Te), antimony (Sb), nickel (Ni), titanium (Ti), aluminum (Al), or tantalum (Ta). Examples of the metal rich oxide layer include tin oxide (SnOx), indium gallium zinc oxide (IGZO), indium tin oxide (ITO), tantalum oxide (TaOx), or other suitable metal rich oxide. In some embodiments, the metal rich oxide layer may be formed by a PVD process that can produce a metal oxide layer having nonstoichiometric ratio of metal to oxide, such as higher metal content. For example, a stoichiometric metal oxide layer can be characterized as MxOy, where M is one or more metals, and the stoichiometric metal to oxide ratio is x to y. In some embodiments, a metal rich oxide layer produced by the PVD process may have a metal to oxide ratio of about 1.5 x-to-y or greater, such as about 2 x-to-y or greater. In other embodiments, the EUV photoresist is a chemically amplified photoresist.

The EUV photoresist is subsequently patterned to form a patterned photoresist. In some embodiments, the metal oxide photoresist is patterned to form a patterned metal oxide photoresist. Patterning the EUV photoresist comprises exposing the photoresist to EUV radiation with a dose comprising a DTS ratio from about 1 mJ/cm² to about 100 mJ/cm², and developing the photoresist to form the patterned photoresist. In some embodiments, the DTS ratio is less than about 100 mJ/cm², such as less than about 80 mJ/cm², such as less than about 60 mJ/cm², such as less than 50 mJ/cm², and such as less than 40 mJ/cm².

The following non-limiting examples are provided to further illustrate embodiments described herein. However, the examples are not intended to be all inclusive and are not intended to limit the scope of the embodiments described herein.

Advantages of the resist underlayer formed by the methods of the present disclosure allow for enhanced EUV lithography performance by reducing DTS ratio during exposure with improvements in LWR and/or min CD.

In one embodiment, a resist underlayer was formed on a silicon substrate by flowing C₃H₆ precursor as a process gas at a temperature of about 150 degrees Celsius in a PECVD chamber at a pressure of about 9 Torr with H₂ as a dilution gas, and applying 200 Watts high frequency (13.56 MHZ) RF power. An EUV spin on metal resist was then applied to the resist underlayer. The substrate with the EUV spin on metal resists disposed over the resist underlayer was then exposed at 13.5 nm wavelength and developed to form a patterned photoresist. The result was compared to a spin on carbon film resist underlayer (reference) which showed the resist underlayer formed by the method of the present disclosure reduced the DTS ratio by about 30%. The resist underlayer also improved LWR by about a 5% reduction to about 2.8 nm, and allowed patterning of 13.6 nm lines and spaces (min CD).

FIG. 3 depicts a flow diagram of a method 300 for forming a resist underlayer on a substrate disposed on a substrate support in a process chamber, in accordance with certain embodiments of the present disclosure. The resist underlayer may be formed directly on the substrate, or on the upper most intermediate layer of one or more intermediate layers disposed on the substrate first. Although the method 300 is described below with reference to a resist underlayer that may be formed on a substrate utilized in EUV lithography, the method 300 may also be used to advantage in other device manufacturing applications. Further, it should also be understood that the operations depicted in FIG. 3 may be performed simultaneously and/or in a different order than the order depicted in FIG. 3.

Method 300 may begin in operation 310 by flowing a underlayer precursor gas into the process chamber. The underlayer precursor gas may further include an inert gas, a dilution gas, a carrier gas or combinations thereof. The underlayer precursor gas may correspond to the underlayer precursor gas as described above with reference to operation 220. In some embodiments, the underlayer precursor gas may comprise a saturated hydrocarbon precursor. The hydrocarbon precursor can be any liquid or gas, though the preferred precursor would be vapor at room temperature to simplify the hardware needed for material metering, control and delivery to the chamber.

At operation 320, a plasma is generated from the underlayer precursor gas in the processing volume of the process chamber. The plasma may be formed by capacitive or inductive means, and may be energized by coupling RF power into the underlayer precursor gas. The RF power may be a dual-frequency RF power that has a high frequency component and a low frequency component. The RF power may be applied at a power level between about 10 W and about 3000 W, such as between about 50 W and about 1500 W, such as between about 100 W and about 800 W, such as about 200 W, 250 W, 300W, 350W, and 400W. In some embodiments, the RF power may be all high-frequency RF power, for example at a frequency of about 13.56 MHZ, or may be a mixture of high-frequency power and low frequency power, for example at a frequency of about 300 KHz or less.

1 A density profile of the plasma may be adjusted by biasing an electrode coupled to a side wall of the process chamber and/or an electrode coupled to the substrate support. Each electrode will typically be controlled to provide impedance for a selected current to flow through the electrode. A resonant tuning circuit is typically coupled to each electrode and to ground, and components for the resonant tuning circuit are selected, with at least one variable component, so the impedance can be adjusted dynamically to maintain the target current flow. The current flow through each electrode may be controlled to a value between about 0 A and about 30 A or between about 1 A and about 30 A.

In operation 330, after the plasma is generated in the process chamber, the resist underlayer is deposited on the substrate from the plasma. The deposition process may be carried out at temperatures ranging from −50 degrees Celsius to 600 degrees Celsius. In some embodiments, the deposition process may be performed at about 80 degrees Celsius or about 150 degrees Celsius. The deposition process may be carried out at pressures ranging from 0.1 mTorr to 100 Torr in the processing volume. In some embodiments, the deposition may be performed at about 9 Torr. In some embodiments, the resist underlayer formed may have a thickness between about 10 Å and about 1000 Å, such as between about 30 Å and about 500 Å, such as between about 50 Å and about 300 Å.

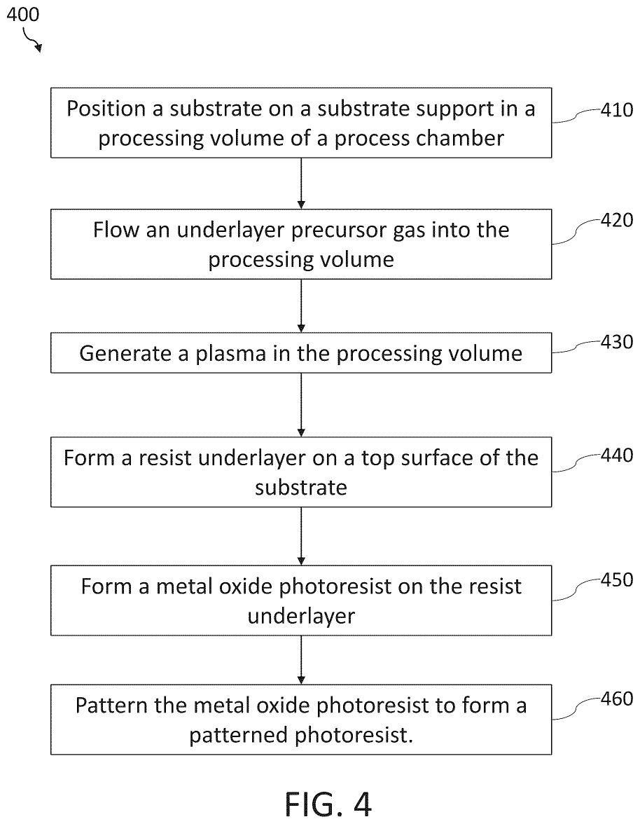

FIG. 4 depicts a flow diagram of a method 400 for forming a resist underlayer on a substrate, in accordance with certain embodiments of the present disclosure. The resist underlayer may be formed directly on the substrate, or on the upper most intermediate layer of one or more intermediate layers disposed on the substrate first. Although the method 400 is described below with reference to a resist underlayer that may be formed on a substrate utilized in EUV lithography, the method 400 may also be used to advantage in other device manufacturing applications. Further, it should also be understood that the operations depicted in FIG. 4 may be performed simultaneously and/or in a different order than the order depicted in FIG. 4.

Method 400 begins in operation 410 by positioning a substrate on a substrate support disposed in a processing volume of a process chamber. The process chamber may be a vapor deposition chamber, such as a chemical vapor deposition (plasma enhanced and/or thermal) process chamber.

In operation 420, a underlayer precursor gas is flowed into the process chamber. The underlayer precursor gas may further include an inert gas, a dilution gas, a carrier gas or combinations thereof. The underlayer precursor gas may correspond to the underlayer precursor gas as described above with reference to operations 220 and 310. In some embodiments, the underlayer precursor gas may comprise a saturated hydrocarbon precursor. The hydrocarbon precursor can be any liquid or gas, though the preferred precursor would be vapor at room temperature to simplify the hardware needed for material metering, control and delivery to the chamber.

At operation 430, a plasma is generated from the underlayer precursor gas in the processing volume of the process chamber. The plasma may be formed by capacitive or inductive means, and may be energized by coupling RF power into the precursor gas mixture. The RF power may be a dual-frequency RF power that has a high frequency component and a low frequency component. The RF power may be applied at a power level between about 10 W and about 3000 W, such as between about 50 W and about 1500 W, such as between about 100 W and about 800 W, such as about 200 W. In some embodiments, the RF power may be all high-frequency RF power, for example at a frequency of about 13.56 MHZ, or may be a mixture of high-frequency power and low frequency power, for example at a frequency of about 300 KHz or less.

A density profile of the plasma may be adjusted by biasing an electrode coupled to a side wall of the process chamber and/or an electrode coupled to the substrate support. Each electrode will typically be controlled to provide impedance for a selected current to flow through the electrode. A resonant tuning circuit is typically coupled to each electrode and to ground, and components for the resonant tuning circuit are selected, with at least one variable component, so the impedance can be adjusted dynamically to maintain the target current flow. The current flow through each electrode may be controlled to a value between about 0 A and about 30 A or between about 1 A and about 30 A.

In operation 440, the resist underlayer is deposited on the substrate using the plasma generated in operation 430. The deposition process may be carried out at temperatures ranging from −50 degrees Celsius to 600 degrees Celsius. The deposition process may be carried out at pressures ranging from 0.1 mTorr to 100 Torr in the processing volume. In some embodiments, the resist underlayer formed may have a thickness between about 10 Å and about 1000 Å, such as between about 30 Å and about 500 Å, such as between about 50 Å and about 300 Å.

At operation 450, a metal oxide photoresist is formed on the resist underlayer. In some embodiments, the metal oxide photoresist can include molecular metal oxide cluster cores, and each core has multiple radiation-sensitive ligands. The metal oxide photoresist is fabricated from a material different from the resist underlayer.

In some embodiments, the metal oxide photoresist may be a metal rich oxide layer that provides ample secondary electrons when excited by EUV radiation. A fully stoichiometric metal oxide layer does not yield as many electrons as the metal rich oxide layer. A metal rich oxide layer including a high Z metal and lower resistance are considered for the EUV process to reduce the EUV dose energies. The high Z metal refers to a metal having an atomic number greater than or equal to 40. In some embodiments, the metal oxide photoresist is a metal rich oxide layer including one or more of tin (Sn), indium (In), gallium (Ga), zinc (Zn), tellurium (Te), antimony (Sb), nickel (Ni), titanium (Ti), aluminum (AI), or tantalum (Ta). Examples of the metal rich oxide layer include tin oxide (SnOx), indium gallium zinc oxide (IGZO), indium tin oxide (ITO), tantalum oxide (TaOx), or other suitable metal rich oxide. In some embodiments, the metal rich oxide layer may be formed by a PVD process that can produce a metal oxide layer having nonstoichiometric ratio of metal to oxide, such as higher metal content. For example, a stoichiometric metal oxide layer can be characterized as MxOy, where M is one or more metals, and the stoichiometric metal to oxide ratio is x to y. In some embodiments, a metal rich oxide layer produced by the PVD process may have a metal to oxide ratio of about 1.5 x-to-y or greater, such as about 2 x-to-y or greater. In other embodiments, the EUV photoresist is a chemically amplified photoresist.

At operation 460, the metal oxide photoresist is patterned to form a patterned photoresist. The metal oxide photoresist can be a positive resist that becomes soluble upon exposure to EUV radiation, or a negative resist that becomes insoluble upon exposure to EUV radiation. Patterning the metal oxide photoresist comprises exposing the metal oxide photoresist to EUV radiation with a dose comprising a DTS ratio from about 1 mJ/cm² to about 100 mJ/cm², and developing the exposed metal oxide photoresist to form the patterned photoresist. In some embodiments, the developer solution is a strong base suitable to rinse away the unexposed portions of the metal oxide photoresist. In some embodiments, the DTS ratio is less than 100 mJ/cm², such as less than 80 mJ/cm², such as less than 50 mJ/cm², such as less than 40 mJ/cm².

In summary, advantages and benefits of the present disclosure provide a process for depositing a resist underlayer on a substrate with reduced sp2 hybridized carbon content. In some embodiments described herein, use of low processing temperature, reduced high frequency RF power, saturated hydrocarbon precursors, and/or higher processing pressure enables fabrication of resist underlayers with low sp2 hybridized carbon content. Use of resist underlayers with low sp2 hybridized carbon content in EUV lithoography provides improvements in sensitivity (DTS ratio) and/or LWR relative to previously available resist underlayers.

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate, comprising:
flowing a underlayer precursor gas into a processing volume of a process chamber having a substrate disposed on a substrate support;
generating a plasma in the processing volume by applying a bias to the substrate support; and
forming a resist underlayer on the substrate, wherein the processing volume is maintained at a temperature between about −50 degrees Celsius and about 600 degrees Celsius.

2. The method of claim 1, wherein the bias is provided at a RF power between about 10 Watts and about 3000 Watts, and at a frequency of between about 200 KHz to about 80 MHz.

3. The method of claim 1, wherein the processing volume is maintained at a pressure between about 0.1 mTorr and about 100 Torr.

4. The method of claim 1, wherein the underlayer precursor gas comprises a saturated hydrocarbon precursor.

5. The method of claim 1, wherein the underlayer precursor gas comprises a dopant precursor comprising nitrogen (N), fluorine (F), iodine (I), oxygen (O), silicon (Si), boron (B), tungsten (W), tin (Sn), lead (Pb), germanium (Ge), or mixtures thereof.

6. The method of claim 1, further comprising flowing a dilution gas comprising He, Ar, Xe, H₂, or combinations thereof.

7. The method of claim 1, wherein the resist underlayer comprises a thickness between about 30 521 and about 500 Å.

8. The method of claim 1, further comprising:
forming a photoresist on the resist underlayer;
exposing at least a portion of the photoresist to EUV radiation; and
developing the photoresist to form a patterned photoresist.

9. The method of claim 8, wherein exposing the photoresist comprises subjecting the photoresist to a dose of EUV radiation comprising a DTS ratio that is less than 50 mJ/cm².

10. The method of claim 8, wherein the patterned photoresist comprises a resolution of less than about 20 nm.

11. The method of claim 8, wherein the patterned photoresist comprises a line width roughness of less than about 4 nm.

12. A method of processing a substrate, comprising:
flowing a underlayer precursor gas into a processing volume of a process chamber having a substrate disposed on a substrate support, wherein the processing volume is maintained at a pressure between about 0.1 mTorr and about 100 Torr;
generating a plasma in the processing volume by applying a RF bias to the substrate support;
forming a resist underlayer on the substrate, wherein the processing volume is maintained at a temperature between about 10 degrees Celsius and about 600 degrees Celsius; and
forming a patterned photoresist over the resist underlayer.

13. The method of claim 12, wherein forming the patterned photoresist comprises subjecting a photoresist to a dose of EUV radiation comprising a DTS ratio that is less than about 60 mJ/cm².

14. The method of claim 13, wherein the patterned photoresist comprises a resolution of less than about 20 nm.

15. The method of claim 13, wherein the patterned photoresist comprises a line width roughness of less than about 4 nm.

16. The method of claim 12, wherein the RF bias is provided at a power between about 10 Watts and about 3000 Watts, and at a frequency of from about 200 KHz to about 80 MHz.

17. The method of claim 12, wherein the underlayer precursor gas comprises a saturated hydrocarbon precursor.

18. The method of claim 12, wherein the underlayer precursor gas comprises a dopant precursor comprising nitrogen (N), fluorine (F), iodine (I), oxygen (O), silicon (Si), boron (B), tungsten (W), tin (Sn), lead (Pb), germanium (Ge) containing gases, or mixtures thereof.

19. A method of processing a substrate, comprising:
flowing a underlayer precursor gas into a processing volume of a process chamber having a substrate disposed on a substrate support;
generating a plasma in the processing volume;
forming a resist underlayer on the substrate;
forming a metal oxide photoresist over the resist underlayer;
exposing the metal oxide photoresist to EUV radiation with a dose comprising a DTS ratio less than about 60 mJ/cm²; and
developing the exposed metal oxide photoresist to form a patterned metal oxide photoresist.

20. The method of claim 19, wherein the resist underlayer comprises a thickness between about 30 Å and about 500 Å.
